(19) United States
(12) Patent Application Publication
(10) Pub. No.: US 2025/0045635 A1
(43) Pub. Date: Feb. 6, 2025

(54) INFORMATION PROCESSING APPARATUS, SUBSTRATE PROCESSING APPARATUS, AND INFORMATION PROCESSING METHOD

(71) Applicant: Tokyo Electron Limited, Tokyo (JP)

(72) Inventor: Masahiro YANAGISAWA, Yamanashi (JP)

(21) Appl. No.: 18/783,106

(22) Filed: Jul. 24, 2024

(30) Foreign Application Priority Data
Aug. 3, 2023 (JP) 2023-126874

(51) Int. Cl. G06N 20/00

(52) U.S. Cl. CPC G06N 20/00

(57) ABSTRACT

An information processing apparatus includes a model acquisition unit that acquires a learned model that has learned a relationship between first log information measured during a processing in a first substrate processing apparatus and a first process result indicating a state of a processing target after the processing; a data acquisition unit that acquires second log information measured during a processing in a second substrate processing apparatus and a second process result indicating a state of a processing target after the processing; and a model correction unit that corrects the learned model based on the second log information and the second process result.

### CROSS-REFERENCE TO RELATED APPLICATIONS

This application is based on and claims priority from Japanese Patent Application No. 2023-126874 filed on Aug. 3, 2023, with the Japan Patent Office, the disclosure of which is incorporated herein in its entirety by reference.

### TECHNICAL FIELD

The present disclosure relates to an information processing apparatus, a substrate processing apparatus, and an information processing method.

### BACKGROUND

Techniques for predicting a state of a processing target after processing from log information of a processing apparatus that processes the processing target have been known. For example, International Publication No. 2021/106646 discloses an inference apparatus capable of inferring with high accuracy, regardless of an application target. The inference apparatus disclosed in the International Publication No. 2021/106646 acquires data measured according to a processing of a processing target in a predetermined processing unit of a manufacturing process, adjusts each piece of output data output by processing the data using a plurality of network units previously machine-learned, and outputs an inference result by synthesizing each piece of output data after being adjusted.

### SUMMARY

According to one aspect of the present disclosure, an information processing apparatus includes: a model acquisition unit that acquires a learned model that has learned a relationship between first log information measured during a processing in a first substrate processing apparatus and a first process result indicating a state of a processing target after the processing; a result acquisition unit that acquires second log information measured during a processing in a second substrate processing apparatus and a second process result indicating a state of a processing target after the processing; and a model correction unit that corrects the learned model based on the second log information and the second process result.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a diagram illustrating a flow of transplanting a reference model from one apparatus to another apparatus.

FIG. 2 is a diagram illustrating an example of constant shift.

FIG. 3 is a diagram illustrating a difference in sensitivity.

FIG. 4 is a block diagram illustrating an overall configuration of a substrate processing system.

FIG. 5 is a schematic cross-sectional view illustrating a substrate processing apparatus.

FIG. 6 is a block diagram illustrating a hardware configuration of a virtual measurement apparatus.

FIG. 7 is a block diagram illustrating a functional configuration of the substrate processing system.

FIG. 8 is a flowchart illustrating an example of learning processing.

FIG. 9 is a flowchart illustrating an example of correction processing.

FIG. 10 is a flowchart illustrating an example of measurement processing.

### DETAILED DESCRIPTION

In the following detailed description, reference is made to the accompanying drawings, which form a part thereof. The illustrative embodiments described in the detailed description, drawings, and claims are not meant to be limiting. Other embodiments may be utilized, and other changes may be made without departing from the spirit or scope of the subject matter presented here.

Hereinafter, embodiments of the present disclosure will be described with reference to the drawings. In the respective drawings, the same components may be denoted by the same reference numerals, and overlapping descriptions thereof may be omitted.

### Embodiment

One embodiment of the present disclosure relates to a substrate processing system including a substrate processing apparatus that processes a substrate, which is an example of a processing target. In the embodiment, the substrate processing system includes a virtual measurement apparatus that predicts a process result based on log information of the substrate processing apparatus.

In the related art, sampling inspection using a monitor wafer was performed to control the quality of a semiconductor wafer, which is an example of a substrate. By predicting a process result using a virtual measurement apparatus, it is possible to conduct a virtual total inspection or an instantaneous inspection of the semiconductor wafer after processing. When the virtual measurement apparatus predicts a process result at each point on the semiconductor wafer, it is also possible to inspect in-plane uniformity of the semiconductor wafer. Further, based on a prediction result of the process result, it is possible to promptly detect an abnormality of a substrate processing apparatus.

The virtual measurement apparatus predicts the process result from the log information, using a prediction model that has machine-learned a relationship between the log information and the process result. To generate the prediction model, it is necessary to collect teaching data by conducting experiments multiple times while changing a control knob. However, in the relationship between the log information and the process result, there may be an individual difference in each apparatus. Therefore, when a learned prediction model that has learned based on teaching data collected from one substrate processing apparatus is directly applied to another substrate processing apparatus, prediction accuracy may be degraded.

Meanwhile, it may not be practical to conduct a sufficient number of experiments to generate a prediction model for each substrate processing apparatus, which is a measurement target of the virtual measurement apparatus. Particularly, for a substrate processing apparatus that is already in actual operation, it is difficult to stop the operation of the substrate processing apparatus for a long period of time and experiment the substrate processing apparatus.

In the embodiment, it is considered that a learned prediction model that has learned (hereinafter, also referred to as a “reference model”) based on teaching data acquired from one substrate processing apparatus (hereinafter, also referred to as a “reference apparatus”) is transplanted into another substrate processing apparatus (hereinafter, also referred to as a “transplant target apparatus”). In this case, the reference model is corrected to be suitable for the transplant target apparatus, using a small number of pieces of teaching data acquired from the transplant target apparatus.

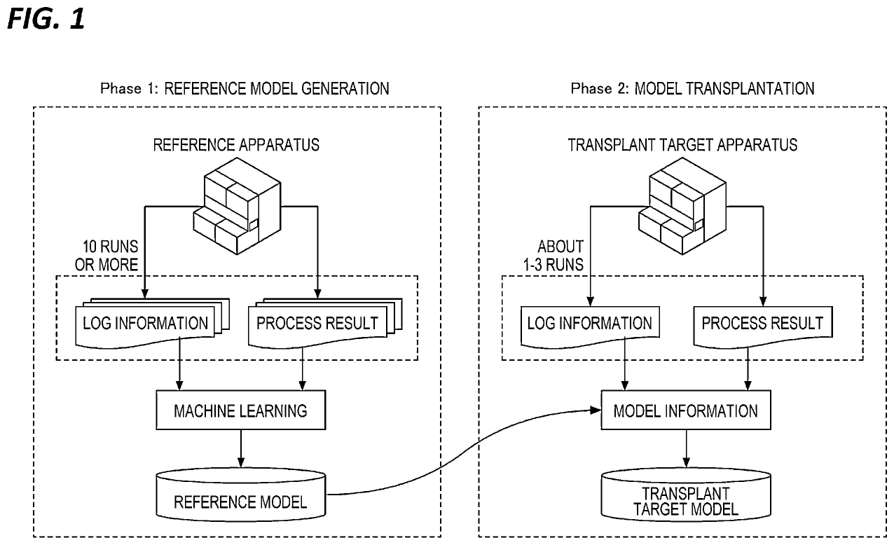

FIG. 1 is a diagram illustrating a flow of transplanting a reference model from one apparatus to another apparatus. As illustrated in FIG. 1, the transplantation of the reference model is performed in two phases. A first phase is the generation of the reference model. A second phase is the transplantation of the reference model into the transplant target apparatus.

In the first phase, first, an experiment is conducted on the reference apparatus to obtain enough pieces of log information and process results. The number of experiments may be at least 10 runs or more. Next, machine-learning is performed using teaching data including the log information and the process results acquired from the reference apparatus, thereby generating a reference model.

In the second phase, first, an experiment is performed on the transplant target apparatus to obtain a small number of pieces of log information and process results. The number of experiments may be at most three runs, but may be one run. Next, the reference model is corrected using the teaching data including the pieces of log information and the process results acquired from the transplant target apparatus, thereby generating a transplant target model. The transplant target model reflects machine differences between the reference apparatus and the transplant target apparatus, and may accurately predict a process result from the log information acquired from the transplant target apparatus.

In an embodiment, the machine differences of the substrate processing apparatuses are classified into a “constant shift” and a “difference in sensitivity.” The constant shift is a phenomenon in which the same degree of difference occurs in process result of each substrate ID. Meanwhile, the substrate ID is identification information that identifies a substrate within the substrate processing apparatus. For example, in a batch apparatus that accommodates a plurality of substrates in a processing container and simultaneously processes the plurality of substrates in an integrated manner, the substrate ID is information indicating a position of the substrate in the processing container.

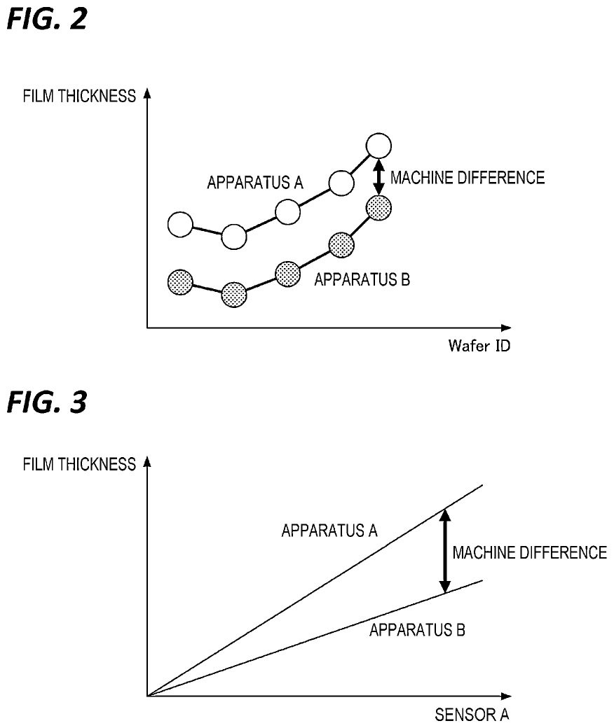

FIG. 2 is a diagram illustrating a constant shift. FIG. 2 illustrates a graph plotting process results of two substrate processing apparatuses (apparatus A and apparatus B). In the graph, an abscissa indicates a wafer ID, which is an example of the substrate ID, and an ordinate indicates a film thickness, which is an example of the process result. As illustrated in FIG. 2, it may be confirmed that a difference in process result for each wafer ID corresponds to the machine difference, and the machine difference for each wafer ID has approximately the same value.

The difference in sensitivity is a difference in the amount of change of the process results when sensor data changes. Meanwhile, the sensor data is data such as temperature, pressure, or a gas flow, which may be measured by a sensor installed in a substrate processing apparatus.

FIG. 3 is a diagram illustrating a difference in sensitivity. FIG. 3 illustrates a graph plotting process results of two substrate processing apparatuses (apparatus A and apparatus B). In the graph, an abscissa indicates a value measured by a sensor A, which is an example of sensor data, and an ordinate indicates a film thickness, which is an example of the process result. As illustrated in FIG. 3, it may be confirmed that a difference in slopes of straight lines each representing the correlation between the sensor data and the process result for each substrate processing apparatus corresponds to the machine difference, and a change in the process result according to a change in the sensor data is different for each substrate processing apparatus.

In the embodiment, the constant shift is corrected by establishing the prediction model as a linear regression model and correcting an intercept thereof with the difference in the process result for each substrate ID. Also, in the embodiment, the difference in sensitivity is corrected by weighted regression of the teaching data acquired from each substrate processing apparatus. Accordingly, by correcting the machine difference between the reference apparatus and the transplant target apparatus in terms of both the constant shift and the difference in sensitivity, it is possible to generate a prediction model suitable for the transplant target apparatus.

### <System Configuration>

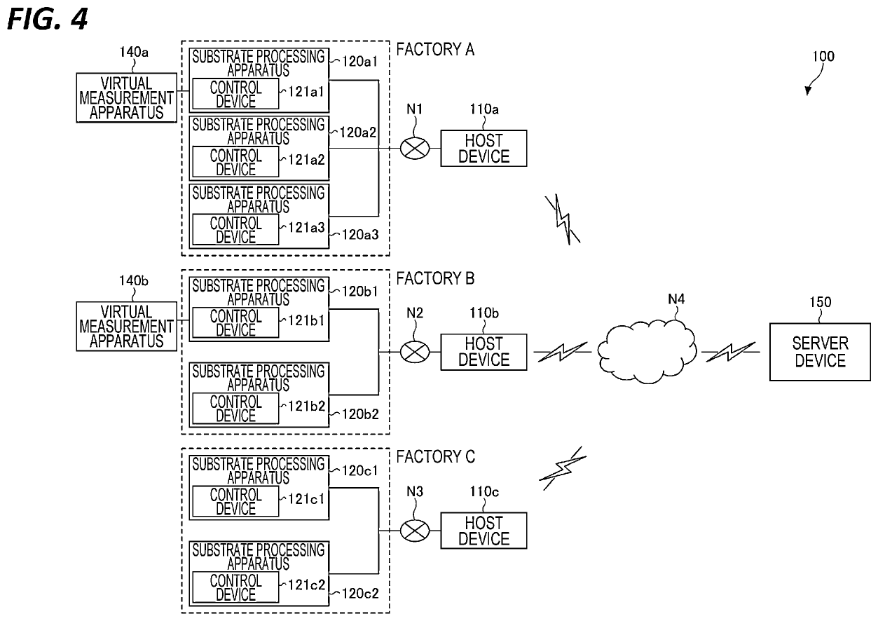

An overall configuration of the substrate processing system in the embodiment will be described with reference to FIG. 4. FIG. 4 is a block diagram illustrating an overall configuration of the substrate processing system in the embodiment.

As illustrated in FIG. 4, a substrate processing system 100 includes substrate processing apparatuses 120a1 to 120a3 and control devices 121a1 to 121a3 in a factory A. The substrate processing apparatuses 120a1 to 120a3 and the control devices 121al to 121a3 are connected in a wired or wireless manner.

In addition, the substrate processing system 100 includes substrate processing apparatuses 120b1 and 120b2 and control devices 121b1 and 121b2 in a factory B. The substrate processing apparatuses 120b1 and 120b2 and the control devices 121b1 and 121b2 are connected in a wired or wireless manner.

In addition, the substrate processing system 100 includes substrate processing apparatuses 120c1 and 120c2 and control devices 121c1 and 121c2 in a factory C. The substrate processing apparatuses 120c1 and 120c2 and the control devices 121c1 and 121c2 are connected in a wired or wireless manner.

The substrate processing apparatuses 120a1 to 120a3, the substrate processing apparatuses 120b1 and 120b2, and the substrate processing apparatuses 121c1 and 121c2 are connected to host devices 110a, 110b, and 110c, respectively, via networks N1 to N3. Under the control of each control device based on instructions from the host devices 110a, 110b, and 110c, each substrate processing apparatus executes a substrate processing. The host devices 110a, 110b, and 110c are connected to a server device 150 via a network N4, such as the Internet.

In the following description, the substrate processing apparatuses 120a1 to 120a3, 120b1, 120b2, 120c1, and 120c2 are also collectively referred to as a substrate processing apparatus 120. In addition, the control devices 121a1 to 121a3, 121b1, 121b2, 121c1, and 121c2 are also collectively referred to as a control device 121. The host devices 110a, 110b, and 110c are also collectively referred to as a host device 110.

The substrate processing apparatuses 120a1 to 120a3, the substrate processing apparatuses 120b1 and 120b2, and the substrate processing apparatuses 120c1 and 120c2 store in their own apparatuses a wide range of data that they each manage.

A virtual measurement apparatus 140a is connected to the substrate processing apparatus 120a1 in a wired or wireless manner. A virtual measurement apparatus 140b is connected to the substrate processing apparatus 120b1 in a wired or wireless manner. The virtual measurement apparatus 140a is an example of a reference apparatus. The virtual measurement apparatus 140b is an example of a transplant target apparatus. FIG. 4 illustrates that the virtual measurement apparatus 140a is connected to the substrate processing apparatus 120a1 and the virtual measurement apparatus 140b is connected to the substrate processing apparatus 120b1. However, the present disclosure is not limited thereto, as long as the virtual measurement apparatus 140a and the virtual measurement apparatus 140b may be connected to different substrate processing apparatuses 120.

The substrate processing system 100 illustrated in FIG. 4 is provided by way of an example, and examples of various system configurations may be provided depending on usage or purposes. The classification of apparatuses such as the host device 110, the substrate processing apparatus 120, the control device 121, the virtual measurement apparatus 140, and the server device 150 illustrated in FIG. 4 is provided by way of an example. For example, the number of factories, the number of host devices 110, the number of substrate processing apparatuses 120, the number of control devices 121, and the number of virtual measurement apparatuses 140 are provided by way of examples and are not limited thereto.

For example, the substrate processing system 100 may have various configurations such as a configuration in which at least two of the host device 110, the substrate processing apparatus 120, the control device 121, the virtual measurement apparatus 140, and the server device 150 are integrated or they are further separated. For example, the control device 121 may control a plurality of substrate processing apparatuses 120 in an integrated manner, or a single control device 121 may be provided for each substrate processing apparatus 120, or the control device 121 may be integrated with the substrate processing apparatus 120.

The virtual measurement apparatus 140 may be implemented by the host device 110, or may be implemented by the server device 150. In this case, the virtual measurement apparatus 140 is unnecessary. Furthermore, the virtual measurement apparatus 140 may be implemented by the control device 121. The virtual measurement apparatus 140 may be implemented by a control device (not illustrated) that controls a plurality of control devices 121 in an integrated manner.

### <Substrate Processing Apparatus>

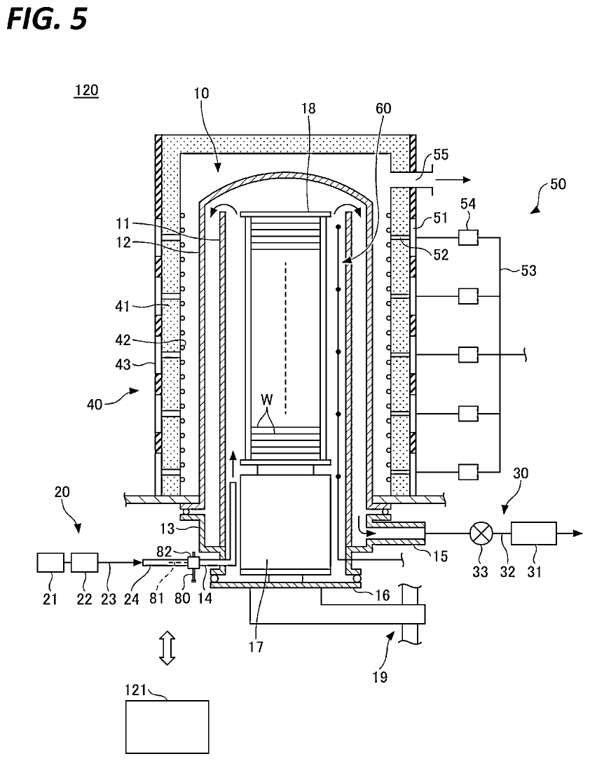

An example of a substrate processing apparatus in the embodiment will be described with reference to FIG. 5. FIG. 5 is a schematic cross-sectional view illustrating a vertical-type heat treatment apparatus, which is an example of a substrate processing apparatus in the embodiment.

A vertical-type heat treatment apparatus 120 in the embodiment is a substrate processing apparatus that accommodates a plurality of semiconductor wafers W, which are an example of processing targets, at once and performs heat treatment thereon, such as oxidation, diffusion, or low-pressure chemical vapor deposition (CVD). As illustrated in FIG. 5, the vertical-type heat treatment apparatus 120 includes a processing container 10, a gas supply unit 20, an exhaust port 30, a heating unit 40, a cooling unit 50, and the control device 121.

The processing container 10 has an approximately cylindrical shape. The processing container 10 includes an inner tube 11, an outer tube 12, a manifold 13, an injector 14, a gas outlet 15, and a cover 16. The inner tube 11 has an approximately cylindrical shape. The outer tube 12 has an approximately cylindrical shape with a ceiling, and the inner tube 11 and the outer tube 12 form a double-tube structure. The inner tube 11 and the outer tube 12 are formed of a heat-resistant material, such as quartz, for example.

The manifold 13 has an approximately cylindrical shape. The manifold 13 supports lower ends of the inner tube 11 and the outer tube 12. The manifold 13 is formed of stainless steel, for example. The injector 14 penetrates the manifold 13 and extends horizontally within the inner tube 11, and bends in an L-shape and extends upwardly within the inner tube 11. The injector 14 has a base end connected to a gas introduction pipe 24 and an open front end. The injector 14 ejects a processing gas (hereinafter, simply referred to as “gas”) introduced through the gas introduction pipe 24 into the inner tube 11 from an opening at the front end. One or more injectors 14 may be provided.

The gas outlet 15 is formed in the manifold 13. The processing gas is exhausted by the exhaust port 30 through the gas outlet 15. The cover 16 hermetically seals an opening at a bottom of the manifold 13. The cover 16 is formed, for example, of stainless steel. On the cover 16, a wafer boat (substrate holding mechanism) 18 is disposed via a heat insulation tank 17. The heat insulation tank 17 and the wafer boat 18 are formed of a heat-resistant material, such as quartz, for example.

The wafer boat 18 holds a plurality of semiconductor wafers W approximately horizontally with predetermined intervals in a vertical direction. A lifting mechanism 19 raises the cover 16, so that the wafer boat 18 is carried (loaded) into the processing container 10 and accommodated within the processing container 10. The lifting mechanism 19 lowers the cover 16, so that the wafer boat 18 is carried out (unloaded) from the processing container 10.

The gas supply unit 20 includes a gas source 21, an integrated gas system (IGS) 22, an external pipe 23, and the gas introduction pipe 24. The gas source 21 is a source of processing gases and includes, for example, a film formation gas source, a cleaning gas source, and a purge gas source. The IGS 22 is an integrated circuit of gas pipes and includes a group of pipes connected to the film formation gas source, the cleaning gas source, and the purge gas source, respectively. A flow control unit is installed in the IGS 22 to control a flow of a gas flowing through each pipe. The flow control unit includes, for example, a mass flow controller, and an opening/closing valve.

The IGS 22 is connected to the external pipe 23. The external pipe 23 is connected to the gas introduction pipe 24. A heater (not illustrated) is wound around an outer circumference of the external pipe 23 to heat the external pipe 23. The gas introduction pipe 24 is connected to the processing container 10 to introduce a gas into the processing container 10. For example, a flow of the processing gas from the gas source 21 is controlled by the flow control unit within the IGS 22. The processing gas from the gas source 21 is heated as it flows through the external pipe 23, and then, the processing gas flows into the gas introduction pipe 24 and is supplied from the gas introduction pipe 24 to the processing container 10 via the injector 14. The injector 14 functions as a gas inlet of the processing container 10.

Near the gas inlet of the processing container 10, a joint 82 for a gas pipe connected to the gas introduction pipe 24 is installed. A temperature sensor 80 is configured to penetrate the joint 82. The temperature sensor 80 is configured to measure the temperature of the gas in the gas introduction pipe 24. The temperature sensor 80 transmits the measured temperature to the control device 121. In addition, a second heater 81 is disposed in the gas introduction pipe 24, and the second heater 81 is configured to heat the gas in the gas introduction pipe 24.

The exhaust port 30 includes an exhaust unit 31, an exhaust pipe 32, and a pressure controller 33. The exhaust unit 31 is a vacuum pump, such as a dry pump or a turbomolecular pump. The pressure controller 33 is installed to the exhaust pipe 32 and adjusts conductance of the exhaust pipe 32 to control a pressure within the processing container 10. The pressure controller 33 is, for example, an automatic pressure control valve.

The heating unit 40 includes an insulator 41, a first heater 42, and an outer cover 43. The insulator 41 has an approximately cylindrical shape and is provided around a periphery of the outer tube 12. The insulator 41 is formed of silica and alumina as main components. The first heater 42 is linear and is installed around an inner circumference of the insulator 41 in a spiral or meandering manner. The first heater 42 is divided into a plurality of zones in a height direction of the processing container 10 and configured to perform temperature control. The outer cover 43 is provided to cover an outer circumference of the insulator 41. The outer cover 43 reinforces the insulator 41 while maintaining the shape of the insulator 41. The outer cover 43 is formed of a metal, such as stainless steel. In addition, a water-cooling jacket (not illustrated) may be installed on an outer circumference of the outer cover 43 to suppress a thermal influence of the heating element 40 to the outside. The heating unit 40 heats the processing container 10 with heat generated by the first heater 42.

The cooling unit 50 supplies a cooling fluid to the processing container 10 to cool the semiconductor wafer W in the processing container 10. The cooling fluid may be, for example, the air. The cooling unit 50 supplies the cooling fluid to the processing container 10, for example, when rapidly cooling the semiconductor wafer W after heat treatment.

The cooling unit 50 includes a fluid channel 51, ejection holes 52, a distribution channel 53, a flow regulator 54, and an arrangement port 55.

A plurality of fluid channels 51 are formed in the height direction between the insulator 41 and the outer cover 43. The fluid channels 51 are, for example, channels formed on an outside of the insulator 41 in a circumferential direction thereof. The ejection hole 52 penetrates through the insulator 41 from each fluid channel 51 and ejects the cooling fluid into a space between the outer tube 12 and the insulator 41. The distribution channel 53 is installed outside the outer cover 43 and is configured to distribute and supply the cooling fluid to each fluid channel 51. The flow regulator 54 is installed to the distribution channels 53 and regulates the flow of the cooling fluid supplied to the fluid channel 51.

The arrangement port 55 is provided above a plurality of the ejection holes 52 and discharges the cooling fluid supplied to the space between the outer tube 12 and the insulator 41 to the outside of the processing container 10. The cooling fluid discharged to the outside of the processing container 10 is cooled, for example, by a heat exchanger, and is supplied back to the distribution channel 53. However, the cooling fluid discharged to the outside of the processing container 10 may be discharged without being reused.

A temperature sensor 60 detects a temperature within the processing container 10. The temperature sensor 60 is installed, for example, within the inner tube 11. However, the temperature sensor 60 may be installed in any location where the temperature within the processing container 10 may be detected, for example, may be installed in a space between the inner tube 11 and the outer tube 12. The temperature sensor 60 includes a plurality of temperature measurement portions installed at different positions in the height direction, for example, corresponding to the plurality of zones. The plurality of temperature measurement portions may be, for example, thermocouples, or temperature measurement resistors. The temperature sensor 60 transmits temperatures detected the plurality of temperature measurement portions to the control device 121.

The control device 121 controls an operation of the vertical-type heat treatment apparatus 120, thereby controlling a semiconductor process executed in the vertical-type heat treatment apparatus 120. The control device 121 may be, for example, a computer.

### <Hardware Configuration>

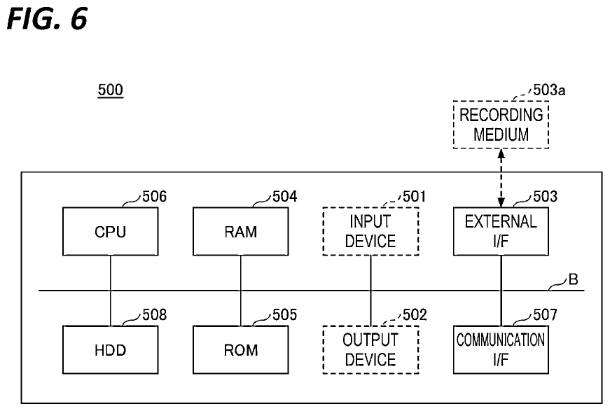

The host device 110, the control device 121, the virtual measurement apparatus 140, and the server device 150 included in the substrate processing system 100 illustrated in FIG. 4 are implemented by a computer with a hardware configuration, for example, as illustrated in FIG. 6. FIG. 6 is a block diagram illustrating a hardware configuration of a computer in the embodiment of the present disclosure.

As illustrated in FIG. 6, a computer 500 of the embodiment includes an input device 501, an output device 502, an external I/F (interface) 503, a random access memory (RAM) 504, a read only memory (ROM) 505, a central processing unit (CPU) 506, a communication I/F 507, and a hard disk drive (HDD) 508, each of which is connected by a bus B. Meanwhile, the input device 501 and the output device 502 may be connected and used as needed.

The input device 501 is a keyboard, a mouse, or a touch panel and is used to input each operational signal by an operator. The output device 502 is a display and displays a result of processing by the computer 500. The communication I/F 507 is an interface that connects the computer 500 to the network. The HDD 508 is an example of a non-volatile storage device that stores programs or data.

The external I/F 503 is an interface to an external device. The computer 500 may perform reading and/or recording on a recording medium 503a, such as a secure digital (SD) memory card, via the external I/F 503. The ROM 505 is an example of a non-volatile semiconductor memory (storage device) in which programs or data are stored. The RAM 504 is an example of a volatile semiconductor memory (storage device) that temporarily holds programs and/or data.

The CPU 506 is a computing device that reads programs or data from the storage device such as the ROM 505 or the HDD 508 and executes a processing to implement control or functions of the entire computer 500.

### <Functional Configuration>

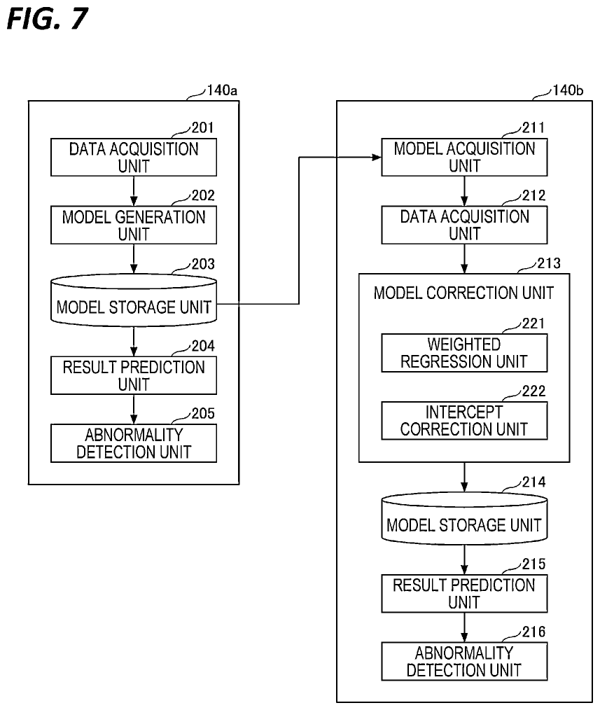

The functional configuration of the virtual measurement apparatus in the embodiment will be described with reference to FIG. 7. FIG. 7 illustrates a functional configuration of the virtual measurement apparatus in the embodiment.

### «Virtual Measurement Apparatus 140a (Reference Apparatus)»

As illustrated in FIG. 7, the virtual measurement apparatus 140a of the embodiment includes a data acquisition unit 201, a model generation unit 202, a model storage unit 203, a result prediction unit 204, and an abnormality detection unit 205.

The model storage unit 203 is implemented, for example, by the RAM 504 or HDD 508 illustrated in FIG. 6. The data acquisition unit 201, the model generation unit 202, the result prediction unit 204, and the abnormality detection unit 205 are implemented by, for example, the CPU 506 illustrated in FIG. 6, executing a program loaded on the RAM 504.

The data acquisition unit 201 acquires log information (an example of first log information) and a process result (an example of a first process result) from the substrate processing apparatus 120a1 (an example of a first substrate processing apparatus).

The log information is sensor data measured while the substrate processing apparatus 120a1 executes a process (e.g., during the processing of a processing target). In the embodiment, the log information may include, for example, temperature, a gas flow rate, a cumulative film thickness, and plasma power. The log information is not limited thereto, and may include any data that may be measured by sensors (e.g., the temperature sensor 60 and the temperature sensor 80 illustrated in FIG. 5) of the substrate processing apparatus 120.

The process result is measurement data acquired by measuring a state of a processed substrate after a process has completed in the substrate processing apparatus 120a1. In the embodiment, the process result may include, for example, a film thickness, a differential refractive index (RI), film stress, film density, a film etch rate, and the number of particles. The process result is not limited thereto, and may include any data that may be measured from the substrate after a processing thereof in the substrate processing apparatus 120a1.

The model generation unit 202 generates a reference model based on the log information and the process result acquired by the data acquisition unit 201. The model generation unit 202 performs machine-learning on a relationship between the log information and the process result, using teaching data including the log information and the process result. In the embodiment, the model generation unit 202 generates a linear regression model as the reference model by performing regression analysis on the teaching data.

The model storage unit 203 stores the reference model. The reference model is a learned prediction model generated by the model generation unit 202.

The result prediction unit 204 predicts a process result (an example of a third process result) from log information (an example of third log information) acquired from the substrate processing apparatus 120a1, based on the reference model read from the model storage unit 203.

The abnormality detection unit 205 detects an abnormality in the substrate processing apparatus 120a1 based on a prediction result of the process result, which is predicted by the result prediction unit 204. The abnormality detection unit 205 may detect an abnormality in the substrate processing apparatus 120a1, for example, by comparing an item included in the process result with a predetermined threshold value. The abnormality detection unit 205 may detect an abnormality in the substrate processing apparatus 120a1 based on a predetermined rule or machine-learned model.

When detecting an abnormality in the substrate processing apparatus 120a1, the abnormality detection unit 216 notifies a predetermined notification destination that the abnormality has been detected. The notification destination may be, for example, an external monitoring apparatus, a virtual measurement apparatus 140a, or a display of the control device 121al.

### «Virtual Measurement Apparatus 140b (Transplant Target Apparatus)»

As illustrated in FIG. 7, the virtual measurement apparatus 140b in the embodiment includes a model acquisition unit 211, a data acquisition unit 212, a model correction unit 213, a model storage unit 214, a result prediction unit 215, and an abnormality detection unit 216. The model correction unit 213 includes a weighted regression unit 221, and an intercept correction unit 222.

The model storage unit 214 is implemented, for example, by the RAM 504 or HDD 508 illustrated in FIG. 6. The model acquisition unit 211, the data acquisition unit 212, the model correction unit 213, the result prediction unit 215, and the abnormality detection unit 216 are implemented by the CPU 506 illustrated in FIG. 6, executing a program loaded on the RAM 504.

The model acquisition unit 211 acquires the reference model from the virtual measurement apparatus 140a. The model acquisition unit 211 may read the reference model stored in the virtual measurement apparatus 140a, or may acquire a reference model by receiving the reference model transmitted from the virtual measurement apparatus 140a.

The data acquisition unit 212 acquires log information (an example of second log information) and a process result (an example of a second process result) from the substrate processing apparatus 120b1 (an example of a second substrate processing apparatus). The log information includes sensor data measured while the substrate processing apparatus 120b1 executes a process. The process result is measurement data acquired by measuring a state of a processed substrate after a process has completed in the substrate processing apparatus 120b1. Items included in the log information and the process result are identical to the log information and the process result acquired by the data acquisition unit 201 of the virtual measurement apparatus 140a.

The model correction unit 213 corrects the reference model acquired by the model acquisition unit 211, based on the log information and the process result acquired by the data acquisition unit 212. The model correction unit 213 generates a corrected prediction model (transplant target model) by executing the weighted regression unit 221 and the intercept correction unit 222, respectively.

The weighted regression unit 221 corrects a difference in sensitivity between the substrate processing apparatus 120a1 and the substrate processing apparatus 120b1. Specifically, the weighted regression unit 221 first acquires, from the virtual measurement apparatus 140a, the teaching data (an example of first teaching data) when the reference model was generated. The teaching data includes the log information and the process result acquired by the data acquisition unit 201. Next, the weighted regression unit 221 generates teaching data (an example of second teaching data) including the log information and the process result acquired by the data acquisition unit 212.

Next, the weighted regression unit 221 determines weights to be given to the first teaching data and the second teaching data. In this case, the weighted regression unit 221 sets a weight given to the second teaching data to be greater than a weight given to the first teaching data. Then, the weighted regression unit 221 performs a weighted regression on the first teaching data and the second teaching data. Accordingly, a new prediction model with updated parameters of the reference model is generated.

The intercept correction unit 222 corrects a constant shift between the substrate processing apparatus 120a1 and the substrate processing apparatus 120b1. Specifically, the intercept correction unit 222 first predicts a process result from the log information acquired by the data acquisition unit 212, based on the reference model. Next, the intercept correction unit 222 calculates a difference between the prediction result of the process result and the process result acquired by the data acquisition unit 212. Then, the intercept correction unit 222 corrects an intercept of the reference model with the difference between the prediction result and the process result.

The model storage unit 214 stores the transplant target model. The transplant target model is a corrected prediction model generated by the model correction unit 213.

The result prediction unit 215 predicts a process result (an example of a third process result) from log information (an example of third log information) acquired from the substrate processing apparatus 120b1 based on the transplant target model read from the model storage unit 214.

The abnormality detection unit 216 detects an abnormality in the substrate processing apparatus 120b1 based on the prediction result of the process result, which is predicted by the result prediction unit 215. When detecting an abnormality in the substrate processing apparatus 120b1, the abnormality detection unit 216 notifies a predetermined notification destination that the abnormality has been detected.

### <Processing Sequence>

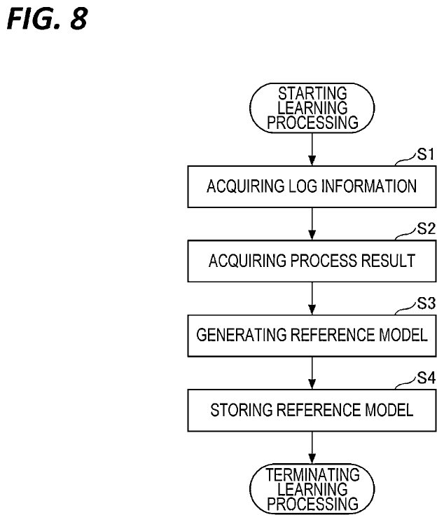

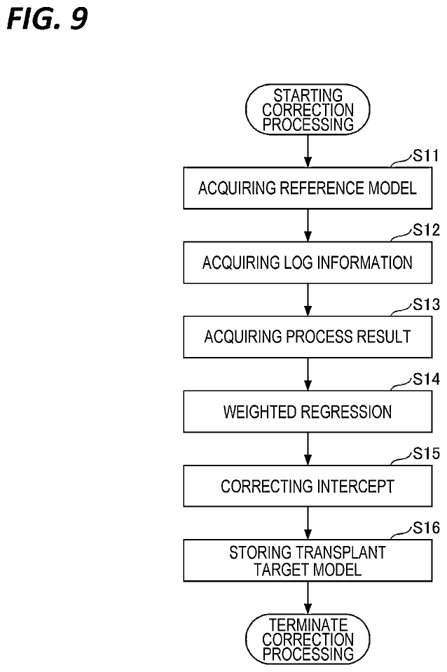

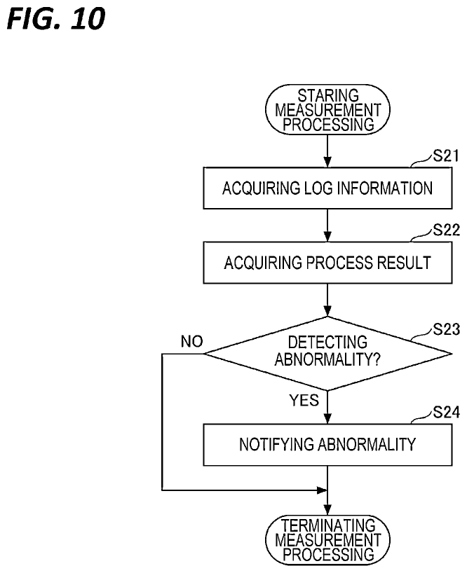

An information processing method executed by the substrate processing system 100 in the embodiment will be described with reference to FIGS. 8 to 10. The information processing method in the embodiment includes learning processing (see, e.g., FIG. 8), correction processing (see, e.g., FIG. 9), and measurement processing (see, e.g., FIG. 10).

### «Learning Processing»

FIG. 8 is a flowchart illustrating an example of learning processing in the embodiment. The learning processing generates a reference model.
In step S1, the data acquisition unit 201 of the virtual measurement apparatus 140a acquires log information from the substrate processing apparatus 120a1. Next, the data acquisition unit 201 sends the acquired log information to the model generation unit 202.
In step S2, the data acquisition unit 201 of the virtual measurement apparatus 140a acquires a process result from the substrate processing apparatus 120a1. Next, the data acquisition unit 201 sends the acquired process result to the model generation unit 202.
In step S3, the model generation unit 202 of the virtual measurement apparatus 140a receives the log information and the process result from the data acquisition unit 201. Next, the model generation unit 202 generates teaching data including the log information and the process result. Then, the model generation unit 202 learns a relationship between the log information and the process result using the teaching data, and generates a reference model.
In step S4, the model generation unit 202 of the virtual measurement apparatus 140a stores the reference model generated in step S3 in the model storage unit 203.

### «Correction Processing»

FIG. 9 is a flowchart illustrating an example of correction processing in the embodiment. The correction processing generates a transplant target model by correcting the reference model.
In step S11, the model acquisition unit 211 of the virtual measurement apparatus 140b acquires the reference model from the virtual measurement apparatus 140a. Next, the model acquisition unit 211 sends the acquired reference model to the model correction unit 213.
In step S12, the data acquisition unit 212 of the virtual measurement apparatus 140b acquires log information from the substrate processing apparatus 120b1. Next, the data acquisition unit 212 sends the acquired log information to the model correction unit 213.
In step S13, the data acquisition unit 212 of the virtual measurement apparatus 140b acquires a process result from the substrate processing apparatus 120b1. Next, the data acquisition unit 212 sends the acquired process result to the model correction unit 213.
In step S14, the model correction unit 213 of the virtual measurement apparatus 140b receives the reference model from the model acquisition unit 211. In addition, the model correction unit 213 receives the log information and the process result from the data acquisition unit 212.

The model correction unit 213 executes the weighted regression unit 221. The weighted regression unit 221 acquires from the virtual measurement apparatus 140a, the first teaching data when the reference model was generated. Next, the weighted regression unit 221 generates the second teaching data including the log information and the process result, received from the data acquisition unit 212. Next, the weighted regression unit 221 determines weights to be given to the first teaching data and the second teaching data. Then, the weighted regression unit 221 performs a weighted regression on the first teaching data and the second teaching data.

In step S15, the model correction unit 213 of the virtual measurement apparatus 140b executes the intercept correction unit 222. The intercept correction unit 222 predicts a process result from the log information received from the data acquisition unit 212 based on the reference model acquired in step S11. Next, the intercept correction unit 222 calculates a difference between a prediction result of the process result and the process result received from the data acquisition unit 212. Then, the intercept correction unit 222 corrects an intercept of the prediction model generated in step S14 with the difference between the prediction result and the process result.

In step S16, the model correction unit 213 of the virtual measurement apparatus 140b acquires the prediction model corrected in step S15 as a transplant target model. Then, the model correction unit 213 stores the acquired transplant target model in the model storage unit 214.

### «Measurement Processing»

FIG. 10 is a flowchart illustrating an example of measurement processing in the embodiment. The measurement processing virtually measures a process result from log information based on a prediction model. For example, the measurement processing predicts a process result based on a prediction model.

The following description describes an example of executing a measurement processing on a transplant target apparatus. The measurement processing may also be executed on a reference apparatus. When executing the measurement processing on the reference apparatus, the virtual measurement apparatus 140b in the following description may be replaced by the virtual measurement apparatus 140a.

In step S21, the data acquisition unit 212 of the virtual measurement apparatus 140b acquires log information from the substrate processing apparatus 120b1. Next, the data acquisition unit 212 sends the acquired log information to the result prediction unit 215.

In step S22, the result prediction unit 215 of the virtual measurement apparatus 140b receives the log information from the data acquisition unit 212. Next, the result prediction unit 215 reads the transplant target model from the model storage unit 214. Next, the result prediction unit 215 inputs the log information into the transplant target model. Based on the input log information, the transplant target model predicts a process result and outputs a prediction result thereof.

The result prediction unit 215 acquires the prediction result of the process result output from the transplant target model. The result prediction unit 215 sends the acquired prediction result to the abnormality detection unit 216. The result prediction unit 215 may display the prediction result of the process result on the output device 502. The result prediction unit 215 may accumulate the prediction result of the process result on the HDD 508.

In step S23, the abnormality detection unit 216 of the virtual measurement apparatus 140b receives the prediction result of the process result from the result prediction unit 215. Next, the abnormality detection unit 216 performs abnormality detection of the substrate processing apparatus 120b1 based on the prediction result of the process result.

When an abnormality is detected in the substrate processing apparatus 120b1 (“YES”), the abnormality detection unit 216 proceeds to step S24. Meanwhile, when an abnormality is not detected in the substrate processing apparatus 120b1 (“NO”), the abnormality detection unit 216 skips step S24 and terminates the measurement processing.

In step S24, the abnormality detection unit 216 of the virtual measurement apparatus 140b notifies a predetermined notification destination that the abnormality has been detected in the substrate processing apparatus 120b1. For example, the abnormality detection unit 216 may notify an external monitoring apparatus via the communication I/F 507 that the abnormality has been detected. In addition, the abnormality detection unit 216 may display the abnormality detected, on the output device 502, for example.

### Effect of Embodiments

The virtual measurement apparatus 140b in the embodiment corrects the learned model that has learned the relationship between the log information and the process result acquired from the substrate processing apparatus 120a, based on the log information and the process result acquired from the substrate processing apparatus 120b. The corrected, learned model reflects a machine difference between the substrate processing apparatus 120a and the substrate processing apparatus 120b, so that the process result may be accurately predicted from the log information acquired from the substrate processing apparatus 120b. Thus, according to the embodiment, prediction accuracy of the process result is improved over the conventional apparatus.

The virtual measurement apparatus 140b in the embodiment, where the learned model is a linear regression model, may correct an intercept of the learned model with a difference between a prediction result obtained by predicting the process result based on the learned model from the log information acquired from the substrate processing apparatus 120b and the process result acquired from the substrate processing apparatus 120b. Thus, according to the embodiment, a learned model that has corrected a constant shift of the substrate processing apparatus 120a and the substrate processing apparatus 120b may be acquired, thereby improving prediction accuracy of the process result over the conventional apparatus.

The virtual measurement apparatus 140b in the embodiment may perform a weighted regression on the teaching data including the log information and the process result acquired from the substrate processing apparatus 120a and the teaching data including the log information and the process result acquired from the substrate processing apparatus 120b. In this case, a weight given to the teaching data acquired from the substrate processing apparatus 120b may be greater than a weight given to the teaching data acquired from the substrate processing apparatus 120a. Accordingly, in the embodiment, a learned model that corrects a difference in sensitivity between the substrate processing apparatus 120a and the substrate processing apparatus 120b may be acquired, thereby improving the prediction accuracy of the process result over the conventional apparatus.

The virtual measurement apparatus 140b in the embodiment may predict the process result from the log information acquired from the substrate processing apparatus 120b based on the learned model. Therefore, according to the embodiment, a virtual total inspection of a processing target processed by the substrate processing apparatus 120b or an instantaneous inspection of a predetermined process may be accurately implemented.

The virtual measurement apparatus 140b in the embodiment may detect an abnormality in the substrate processing apparatus 120b based on a prediction result of the process result. Therefore, according to the embodiment, an abnormality in the substrate processing apparatus 120b may be detected promptly.

The substrate processing apparatus for executing a process including a substrate processing method according to the present disclosure is not limited to a heat treatment apparatus. The substrate processing apparatus may be applied to any type of apparatuses, such as an atomic layer deposition (ALD) apparatus, a capacitively coupled plasma (CCP) apparatus, an inductively coupled plasma (ICP) apparatus, a radial line slot antenna (RLSA) apparatus, an electron cyclotron resonance plasma (ECR) apparatus, and a helicon wave plasma (HWP) apparatus.

In addition, the substrate processing apparatus according to the present disclosure may be applied to any of an apparatus using plasma and an apparatus that does not use plasma, as long as the apparatus performs a predetermined processing (e.g., a film formation processing or an etching processing) on the substrate. Furthermore, the substrate processing apparatus according to the present disclosure may be applied to any of a single-substrate processing apparatus that processes substrates one by one, a batch apparatus that processes a plurality of substrates at once, and a semi-batch apparatus that processes, at once, a smaller number of substrates than the number of substrates processed by the batch apparatus.

According to one aspect, the prediction accuracy of a process result is improved over the conventional apparatus.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. An information processing apparatus comprising:
a model acquisition circuitry configured to acquire a learned model that has learned a relationship between first log information measured during a processing in a first substrate processing apparatus and a first process result indicating a state of a processing target after the processing;
a data acquisition circuitry configured to acquire second log information measured during a processing in a second substrate processing apparatus and a second process result indicating a state of a processing target after the processing; and
a model correction circuitry configured to correct the learned model based on the second log information and the second process result.

2. The information processing apparatus according to claim 1, wherein the model correction circuitry is configured to correct a prediction result of the learned model based on a difference between the second process result and a prediction result obtained by predicting a process result from the second log information based on the learned model.

3. The information processing apparatus according to claim 2, wherein the learned model is a linear regression model, and
the model correction circuitry is configured to correct an intercept of the learned model with the difference.

4. The information processing apparatus according to claim 1, wherein the learned model is a linear regression model, and
the model correction circuitry is configured to perform a weighted regression on first teaching data including the first log information and the first process result, and second teaching data including the second log information and the second process result.

5. The information processing apparatus according to claim 4, wherein a weight given to the second teaching data is greater than a weight given to the first teaching data.

6. The information processing apparatus according to claim 1, further comprising:
a result prediction circuitry configured to predict a third process result indicating the state of the processing target after the processing from third log information measured during the processing in the second substrate processing apparatus, based on the learned model corrected by the model correction circuitry.

7. The information processing apparatus according to claim 6, further comprising:
an abnormality detection circuitry configured to detect an abnormality in the second substrate processing apparatus based on the third process result.

8. A substrate processing apparatus comprising:
a model acquisition circuitry configured to acquire a learned model that has learned a relationship between first log information measured during a processing in another substrate processing apparatus different from the substrate processing apparatus and a first process result indicating a state of a processing target after the processing;
a data acquisition circuitry configured to acquire second log information measured during a processing in the substrate processing apparatus, and a second process result indicating a state of a processing target after the processing; and
a model correction circuitry configured to correct the learned model based on the second log information and the second process result.

9. An information processing method comprising:
acquiring a learned model that has learned a relationship between first log information measured during a processing in a first substrate processing apparatus and a first process result indicating a state of a processing target after the processing;
acquiring second log information measured during a processing in a second substrate processing apparatus and a second process result indicating a state of a processing target after the processing; and
correcting the learned model based on the second log information and the second process result.
